(19) United States
(12) Patent Application Publication
(10) Pub. No.: US 2015/0069519 A1
(43) Pub. Date: Mar. 12, 2015

(54) SEMICONDUCTOR DEVICE

(71) Applicant: Micron Technology, Inc., Boise, ID (US)

(72) Inventors: Mamoru Aoki, Tokyo (JP); Kanji Oishi, Tokyo (JP)

(21) Appl. No.: 14/470,365

(22) Filed: Aug. 27, 2014

(30) Foreign Application Priority Data
Sep. 12, 2013 (JP) 2013-189466

(51) Int. Cl. H01L 27/02; H01L 27/092

(52) U.S. Cl. CPC H01L 27/0203; H01L 27/092
USPC 257/369

(57) ABSTRACT

A semiconductor device includes a first transistor having a gate, a source/drain and a drain/source coupled to a first node, a first power and the first node, respectively; a second transistor having a gate, a source/drain and a drain/source coupled to the first node, the first power and a third node, respectively; a third transistor having a gate, a source/drain and a drain/source coupled to a reference, a second node and the first node, respectively; a fourth transistor having a gate, a source/drain and a drain/source coupled to an input, the second node and the third node, respectively; a fifth transistor having a gate, a source/drain and a drain/source coupled to the first node, a second power and the second node, respectively; and a sixth transistor having a gate, a source/drain and a drain/source coupled to the reference, the second power and the second node, respectively.

### RELATED REFERENCE

This application is based upon and claims the benefit of priority from Japanese patent application No. 2013-189466, filed on Sep. 12, 2013, the disclosure of which is incorporated herein by reference in its entirety.

### BACKGROUND

Some semiconductor devices, such as dynamic random access memory (DRAM) devices, include a differential amplifier circuit.

### BRIEF DESCRIPTION OF THE DRAWINGS

The features and advantages of the various embodiments will be more apparent from the following description, taken in conjunction with the accompanying drawings, in which:

FIG. 1 is a schematic drawing showing part of a semiconductor device according to various embodiments;

FIG. 2 is a circuit diagram showing an inner configuration of an input receiver circuit included in the semiconductor device of FIG. 1;

FIG. 3 is a graph showing input-output voltage characteristics of the input receiver circuit of FIG. 2;

FIG. 4A is a graph showing change of voltage at a gate common connecting point (Node11) against variation of a reference voltage (VREF);

FIG. 4B is a graph showing change of main current (Im) against the variation of the reference voltage (VREF);

FIG. 5A is a graph showing the change of the voltage at the gate common connecting point (Node11) against the variation of the reference voltage (VREF);

FIG. 5B is a graph showing change of the main current (Im), subsidiary current (Is) and sum of them (Im+Is) against the variation of the reference voltage (VREF);

FIG. 6 is a drawing showing a practical configuration of a transistor used in the input receiver circuit of FIG. 2 as a current source;

FIG. 7 is a circuit diagram showing an inner configuration of an input receiver circuit included in a semiconductor device according to various embodiments; and

FIG. 8 is a circuit diagram showing an inner configuration of an input receiver circuit included in a semiconductor device according to various embodiments.

### DETAILED DESCRIPTION

Those skilled in the art will recognize that many alternative embodiments can be accomplished using the teachings of the present disclosure and that the disclosure is not limited to the embodiments illustrated for explanatory purposes.

There is a semiconductor device, such as a dynamic random access memory (DRAM), which provides an input receiver circuit including a differential amplifier circuit.

The differential amplifier circuit may include a current mirror circuit and a differential circuit (including a current source). A transistor can be used for the current source of the differential circuit.

When the differential amplifier circuit is configured so that the transistor, which is the current source, operates as a constant current source by supplying a constant voltage to a gate thereof, it has characteristics changed by the variation of the ground potential. Thus, in a related differential amplifier circuit, a gate of a transistor, which is a current source, is coupled to a gate common connection point of a pair of transistors to make up a current mirror circuit to operate without influence of variation of the ground potential. Such a differential amplifier is disclosed in Japanese Patent No. JP-A-1998-322142, for example.

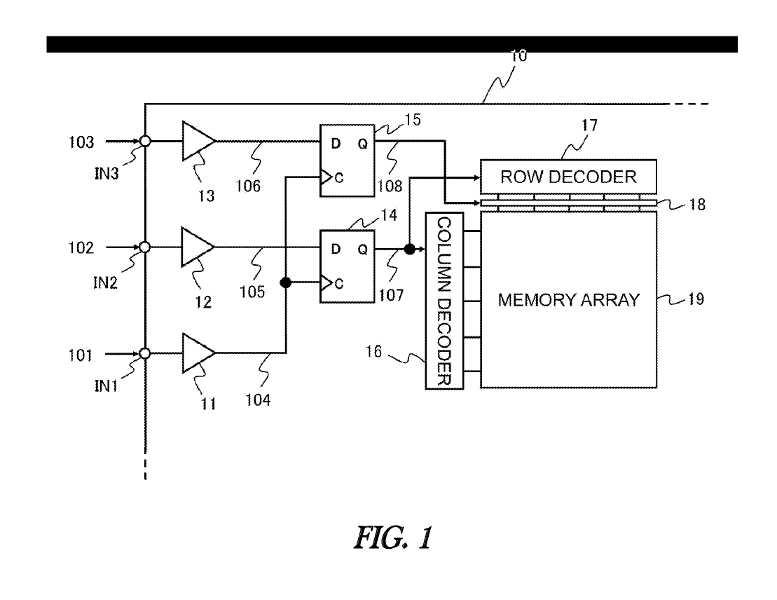

FIG. 1 is a schematic drawing showing a main part of a semiconductor device according to various embodiments. An illustrated semiconductor device 10 may include a semiconductor memory device, for example a DRAM.

However, the present disclosure is not limited to the DRAM or the semiconductor memory device, and it is applicable to various semiconductor devices each including a differential amplifier circuit. As described later, various embodiments may include an inner configuration of input receiver circuits 11-13. As for other constituent elements, known elements can be used. Accordingly, in respect to the whole configuration of the semiconductor device 10 and an operation thereof, outlines will be described.

The semiconductor device 10 includes a plurality (e.g., three) of input receiver circuits 11-13, flip flop circuits 14 and 15, a column decoder 16, a row decoder 17, a sense amplifier 18, and a memory array 19.

The input receiver circuits 11-13 respectively receive a clock signal 101, an address signal 102 (referred to as control signals), and a data signal 103 as inputs, via external terminals IN1-IN3, and respectively output an internal clock signal 104, an internal address signal 105, and an internal data signal 106.

The flip flop circuits 14 and 15 latch and output the internal address signal 105 and the internal data signal 106 at a timing of a leading edge of the internal clock signal 104, respectively. The flip flop circuit 14 outputs an internal address signal 107 to supply it to the column decoder 16 and the row decoder 17. The flip flop circuit 15 outputs an internal data signal 108 to supply it to the sense amplifier 18.

The column decoder 16 and the row decoder 17 have access to a memory cell included in the memory array 19 in response to the internal address signal 107, and execute a writing operation in response to the internal data signal 108 supplied to the sense amplifier 18. It is possible to execute a reading operation using a data output path (not shown) in the same manner as the writing operation.

Hereinafter, the input receiver circuits 11-13 will be described in more detail. The input receiver circuits 11-13 may be the same in configuration. Accordingly, the description will be made about the input receiver circuit 11.

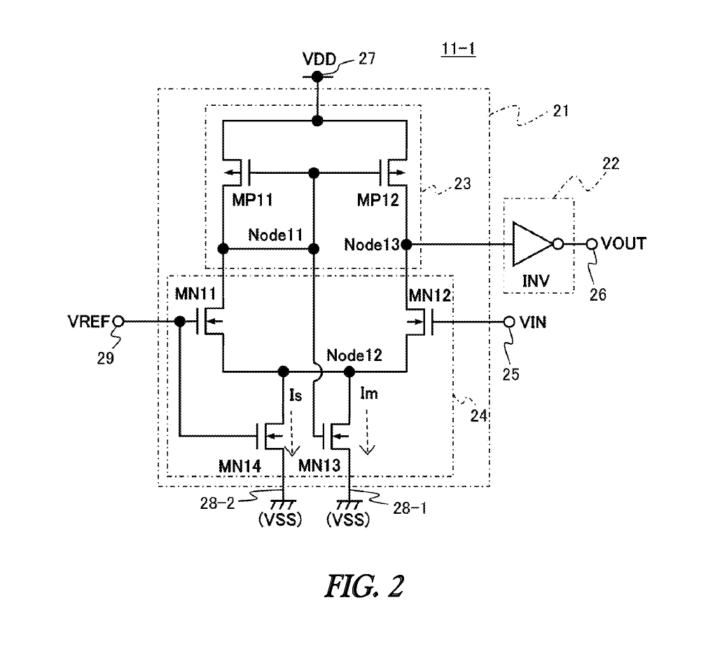

FIG. 2 is a circuit diagram showing an inner configuration of an input receiver circuit 11-1 which shows an example of the input receiver circuit 11.

As shown in FIG. 2, the input receiver circuit 11-1 includes a differential amplifier circuit 21 and an inverter circuit 22. The differential amplifier circuit 21 includes a current mirror circuit 23 and a differential circuit 24. The input receiver circuit 11-1 further includes an input terminal 25, an output terminal 26, a pair of power supply terminals 27 and 28 (28-1 and 28-2), and a reference voltage terminal 29.

The current mirror circuit 23 includes a pair of p-channel metal oxide semiconductor (PMOS) transistors (or third and fourth transistors) MP11 and MP12. The PMOS transistors MP11 and MP12 have gates which are coupled to each other at a connecting point (or a gate common connecting point) Node11. The PMOS transistor MP11 has a drain that is coupled to the connecting point Node11. The PMOS transistors MP11 and MP12 further have sources that are supplied with a power source voltage VDD via the power supply terminal 27.

The differential circuit 24 includes n-channel metal oxide semiconductor (NMOS) transistors (or fifth and sixth transistors) MN11 and MN12 composing a differential pair, and NMOS transistors (or first and second transistors) MN13 and MN14 serving as a current source.

The NMOS transistors MN11 and MN12 respectively have drains coupled to drains of the PMOS transistors MP11 and MP12. Moreover, the NMOS transistors MN11 and MN12 respectively have sources coupled to each other (at a source common connecting point Node12). One of the NMOS transistors MN11 and MN12 (MN11 in this embodiment) is supplied with a reference voltage VREF (e.g. VREF=VDD/2) at a gate thereof via the reference voltage terminal 29, while the other (MN12 in this embodiment) is supplied with an input voltage VIN at a gate thereof via the input terminal 25.

The NMOS transistors MN13 and MN14 serve as the current source for the differential circuit 24 (or the differential amplifier circuit 21). The NMOS transistors MN13 and MN14 have drains that are coupled to the source common connecting point Node12. Moreover, the NMOS transistors MN13 and MN14 have sources that are coupled to the ground (VSS) via the power supply terminals 28-1 and 28-2. One transistor of the NMOS transistors MN13 and MN14 (MN13 in this embodiment) has a gate that is coupled to the gate common connecting point Node11 and configures a main current source circuit. On the other hand, the other transistor of the NMOS transistors MN13 and MN14 (MN14 in this embodiment) has a gate that is coupled to the reference voltage terminal 29 and configures a current adjustment circuit (or a subsidiary current source circuit).

The inverter circuit 22 is coupled between a drain common connecting point Node13 (which is coupled to drains of the PMOS transistor MP12 and the NMOS transistor MN12) and the output terminal 26.

Hereinafter, the description will be made about an operation of the input receiver circuit 11-1 as illustrated in FIG. 2. Here, it is assumed that the PMOS transistors MP11 and MP12, which form a pair, are the same in size, while the NMOS transistors MN11 and MN12 have the same size. However, each pair may have arbitrary ratio in size. In such a case, a ratio of currents passing through the transistors depends on the size ratio of the transistors.

When the input voltage VIN is equal to the reference voltage VREF, currents passing through the NMOS transistors MN11 and MN12 are equal to each other. The total value of the currents is decided by the NMOS transistors MN13 and MN14, which are the current source. The operations of the NMOS transistors MN13 and MN14 are described in detail later, and they serve as a constant current source generally.

When the input voltage VIN becomes higher than the reference voltage VREF, the current passing through the NMOS transistor MN12 tends to increase and the current passing through the NMOS transistor MN11 tends to decrease. At that time, however, the currents supplied through the current mirror circuit 23 to the NMOS transistors MN11 and MN12 have not been changed. Therefore, a drain voltage of the NMOS transistor MN12 becomes low, while a drain voltage of the NMOS transistor MN11 becomes high.

The increase of the drain voltage of the NMOS transistor MN11 may cause an increase of voltage of the gate common connecting point Node11. The voltage of the gate common connecting point Node11 serves as a control voltage for the current mirror circuit 23. The increase of the voltage of the gate common connecting point Node11 may cause reductions of the currents passing the PMOS transistors MP11 and MP12, and thereby may reduce the drain voltage of the PMOS transistors MP11 and MP12. In this way, the increase of the drain voltage of the NMOS transistor NM11 may cause the reduction of the drain voltage of the PMOS transistor MP11. As a result, those drain voltages are countervailed by each other, and the voltage of the gate common connecting point Node11 converges on a predetermined value. Thus, the gate common connecting point Node11 has the voltage that is hardly changed.

On the other hand, the voltage of the drain common connecting point Node13 may be reduced by reductions of the drain voltages of the NMOS transistor MN12 and the PMOS transistor MP12.

The inverter circuit 22 logically inverts the voltage variation of the drain common connecting point Node13 to output it to the output terminal 26. That is, the inverter circuit 22 increases the output voltage VOUT in response to reduction of the voltage of the drain common connecting point Node13.

As mentioned above, the output voltage VOUT increases when the input voltage VIN becomes higher than the reference voltage VREF.

By contrast, when the input voltage VIN becomes lower than the reference voltage VREF, the current passing through the NMOS transistor MN11 tends to increase, and the current passing through the NMOS transistor MN12 tends to decrease. Herewith, the drain voltage of the NMOS transistor MN12 becomes high, while the drain voltage of the NMOS transistor MN11 becomes low.

The reduction of the drain voltage of the NMOS transistor MN11 may cause a reduction of the voltage of the gate common connecting point Node11, and thereby may reduce the currents passing through the PMOS transistors MP11 and MP12. Thus, the drain voltages of the PMOS transistors MP11 and MP12 are increased. That is, the reduction of the drain voltage of the NMOS transistor NM11 may cause the increase of the drain voltage of the PMOS transistor MP11. And then, those drain voltages are countervailed by each other, and the voltage of the gate common connecting point Node11 converges on the predetermined value.

On the other hand, the voltage of the drain common connecting point Node 13 is increased by the increase of the drain voltages of the NMOS transistor MN12 and the PMOS transistor MP12.

The inverter circuit 22 reduces the output voltage VOUT in response to increase of the voltage of the drain common connecting point Node13. Thus, the output voltage VOUT decreases when the input voltage VIN becomes lower than the reference voltage VREF.

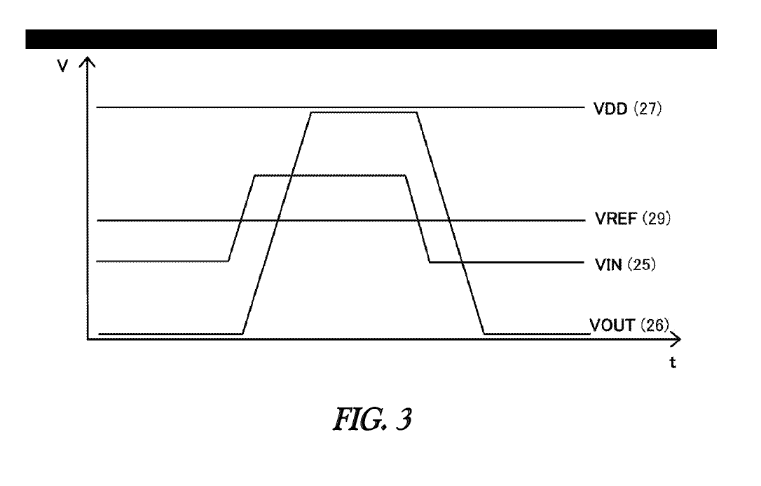

FIG. 3 shows the relationship between the time change of the input voltage VIN and the time change of the output voltage VOUT. In FIG. 3, the horizontal axis represents time (t), while the vertical axis represents voltage (V).

As described above, the voltage of the gate common connecting point Node11 converges on the predetermined value, and hardly changes. Accordingly, the NMOS transistor MN13 whose gate is coupled to the gate common connecting point Node11 operates as the constant current source. If a ground potential (or a difference voltage between VDD and VSS) varies, the voltage of the gate common connecting point Node11 changes according to the variation of the ground potential. Accordingly, the NMOS transistor MN13 operates as the constant current source, even when the ground potential VSS varies. As a result, the differential amplifier circuit 21 demonstrates stable input-output characteristics, which are not influenced by variation of the ground potential VSS.

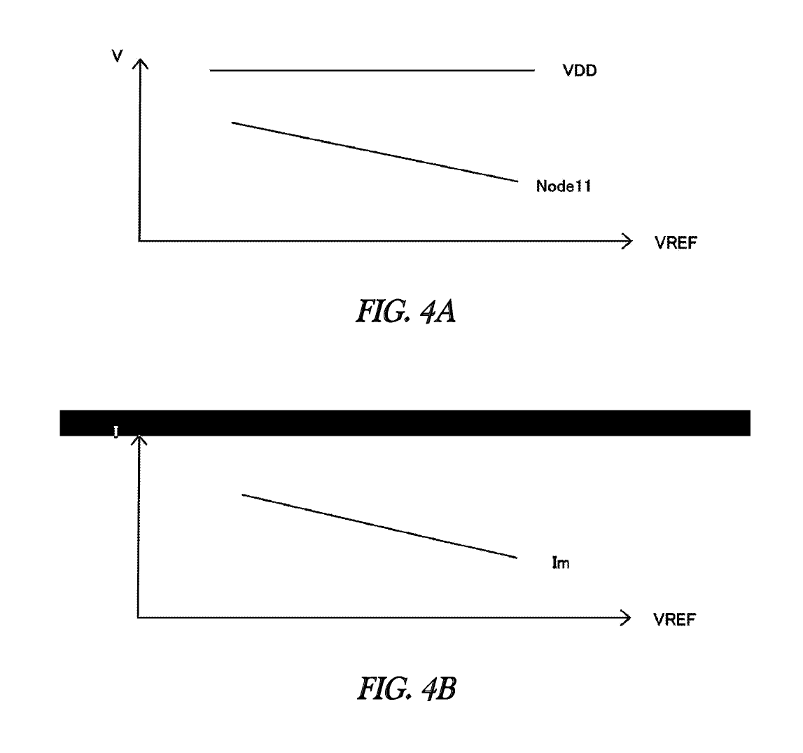

Here, the current passing through the NMOS transistor MN13, i.e. a main current Im, is affected by the variation of the reference voltage VREF. In detail, when the reference voltage VREF varies, the voltage of the gate common connecting point Node11 changes according to the variation of the reference voltage VREF as illustrated in FIG. 4A. Consequently, the main current Im passing through the NMOS transistor MN13 changes according to the variation of the reference voltage VREF as illustrated in FIG. 4B. The change of the main current Im affects the input-output characteristics of the differential amplifier circuit 21. Therefore, in this embodiment, the NMOS transistor MN14 may compensate the change of the main current Im passing through the NMOS transistor MN13 that is caused by the variation of the reference voltage VREF.

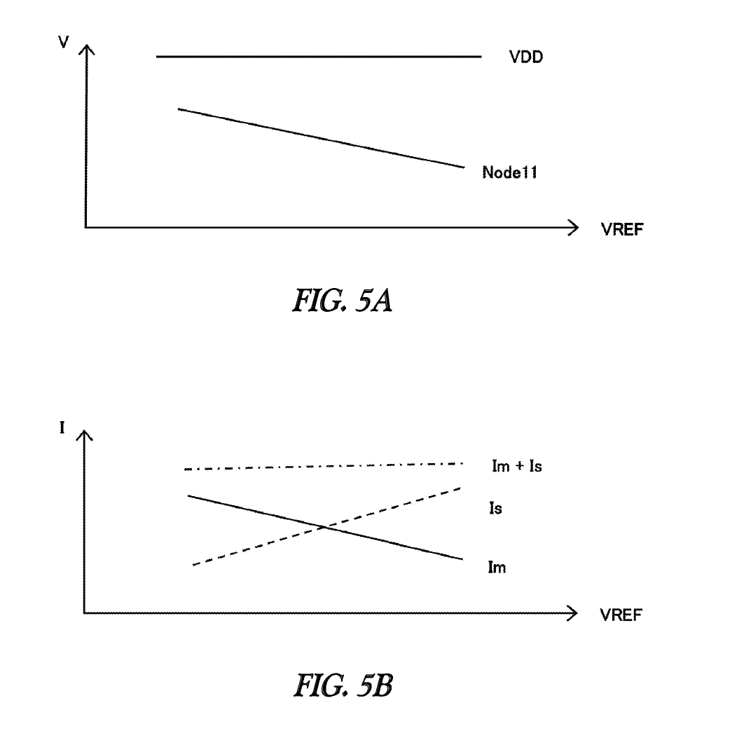

The NMOS transistor MN14 operates as a constant current source to pass a constant current (subsidiary current Is) through it, as long as the reference voltage VREF is constant. In a case where the reference voltage VREF varies, the NMOS transistor MN14 changes the subsidiary current Is according to the variation of the reference voltage VREF. The change of the subsidiary current Is is set to compensate the change of the main current Im passing through the NMOS transistor MN13 as illustrated in FIG. 5B. Thus, the NMOS transistor MN14 operates as a current adjustment circuit to adjust the subsidiary current Is according to the variation of the reference voltage VREF. As a result, the differential amplifier circuit 21 demonstrates stable input-output characteristics that are not affected by variation of the reference voltage VREF.

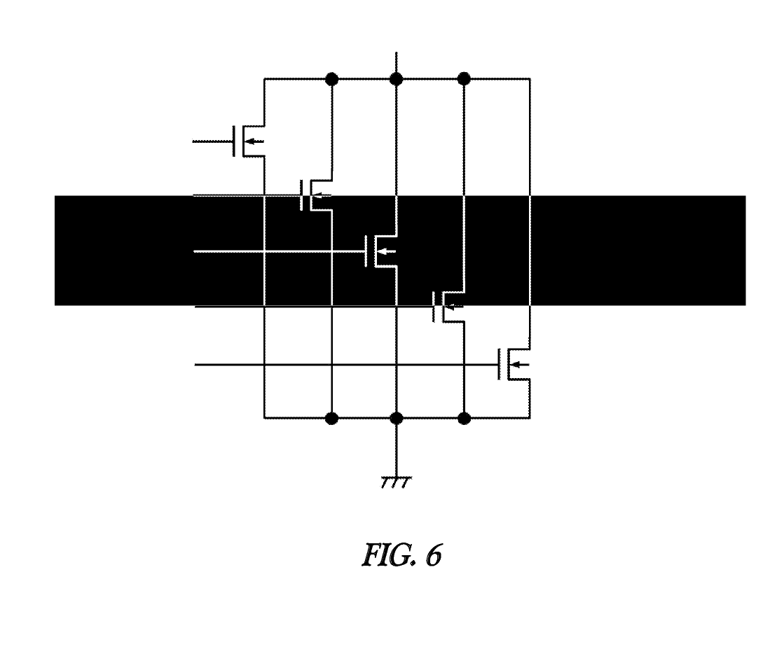

By the way, in FIG. 2, the NMOS transistors MN13 and MN14 are shown as a single transistor each. However, these transistors may be configured as a transistor group each, in which a plurality of transistors are coupled to one another in parallel as illustrated in FIG. 6. According to such a configuration, it is possible to make selectively one or more transistors of the transistor group operable, and thereby to obtain the characteristics desired for a single transistor. Therefore, even though there is characteristics variation of transistors caused by variation in production, it is possible to adjust characteristics of each transistor group, which serves as a single transistor, to obtain the desired characteristics.

It is possible to employ fuses or anti-fuses to make selectively one or more transistors included in the transistor group operable. The operation test of the transistor group is made during or after a manufacturing process of a semiconductor device to find characteristics thereof. On the basis of the found characteristics, fuses are cut, for example, so that one or more transistors are selectively operable and the transistor group has the desired characteristics. In this manner, it is possible to remove the influence of variations in the manufacture that act on the characteristics of the transistor group.

As described above, according to the first embodiment, the NMOS transistor MN13 may remove or suppress the influence of the variation of the ground potential VSS. Moreover, the NMOS transistor MN14 may remove or suppress the influence of the variation of the reference voltage VREF. Because these NMOS transistors MN13 and MN14 are used as the current source of the differential amplifier circuit 21, it is possible to make the input receiver circuit 11-1 have good input-output characteristics regardless of the variation of the ground potential VSS or the variation of the reference voltage VREF.

Next, the description will be made about an input receiver circuit 11-2 according to various embodiments. In some embodiments described previously, the NMOS transistors MN11 and MN12, each of which is one of first and second conductive type transistors, are used for an input stage of the differential amplifier circuit 21. On the other hand, in this second embodiment, PMOS transistors, each of which is the other of the first and second conductive type transistors, are used for the input stage.

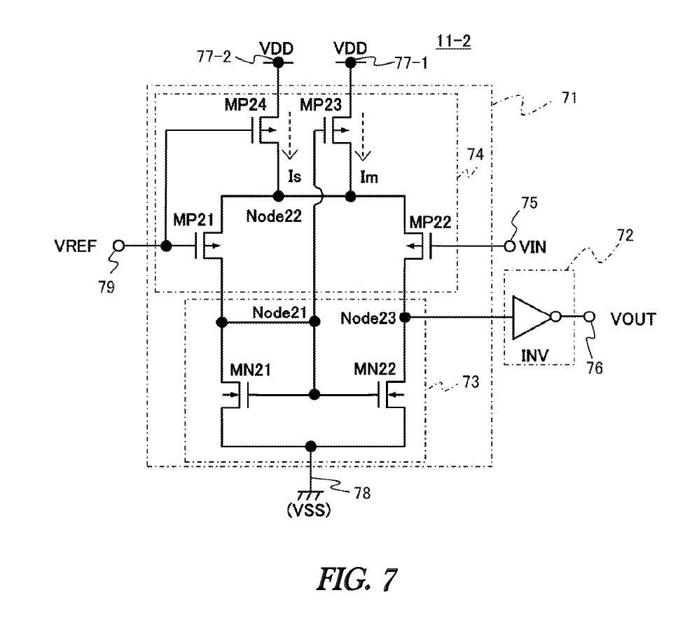

As shown in FIG. 7, the input receiver circuit 11-2 includes a differential amplifier circuit 71 and an inverter circuit 72. The differential amplifier circuit 71 includes a current mirror circuit 73 and a differential circuit 74. The input receiver circuit 11-2 further includes an input terminal 75, an output terminal 76, a pair of power supply terminals 77 (77-1, 77-2) and 78, and a reference voltage terminal 79.

The current mirror circuit 73 includes a pair of NMOS transistors (or third and fourth transistors) MN21 and MN22. The NMOS transistors MN21 and MN22 have gates, which are coupled to each other at a connecting point (or a gate common connecting point) Node21. The NMOS transistor MN21 has a drain, which is coupled to the connecting point Node21. The NMOS transistors MN21 and MN22 further includes sources, which are supplied with the ground potential VSS via the power supply terminal 78.

The differential circuit 74 includes PMOS transistors (or fifth and sixth transistors) MP21 and MP22 composing a differential pair, and PMOS transistors (or first and second transistors) MP23 and MP24 serving as a current source.

The PMOS transistors MP21 and MP22 have drains coupled to drains of the NMOS transistors MN21 and MN22, respectively. Moreover, the PMOS transistors MP21 and MP22 have sources, which are coupled to each other (at a source common connecting point Node22). One of the PMOS transistors MP21 and MP22 (MP21 in this embodiment) is supplied with a reference voltage VREF (e.g. VREF=VDD/2) at a gate thereof via the reference voltage terminal 79, while the other (MP22 in this embodiment) is supplied with an input voltage VIN at a gate thereof via the input terminal 75.

The PMOS transistors MP23 and MP24 serve as the current source for the differential circuit 74 (or the differential amplifier circuit 71). The PMOS transistors MP23 and MP24 have drains, which are coupled to the source common connecting point Node22. Moreover, the PMOS transistors MP23 and MP24 have sources, which are supplied with the power supply voltage VDD via the power supply terminals 77-1 and 77-2. One transistor of the PMOS transistors MP23 and MP24 (MP23 in this embodiment) has a gate, which is coupled to the gate common connecting point Node21 to form a main current source circuit. On the other hand, the other transistor of the PMOS transistors MP23 and MP24 (MP24 in this embodiment) has a gate, which is coupled to the reference voltage terminal 79 and configures a current adjustment circuit (or a subsidiary current source circuit).

The inverter circuit 72 is coupled between a drain common connecting point Node 23 (which is coupled to the drains of the NMOS transistor MN22 and the PMOS transistor MP22) and the output terminal 76.

The input receiver circuit 11-2 operates in a case where currents flow in an inverse direction in the input receiver circuit 11-1. In the present embodiment, it is possible to obtain stable input-output characteristics without the influence of the variation of the reference voltage VREF in the same manner as the first embodiment.

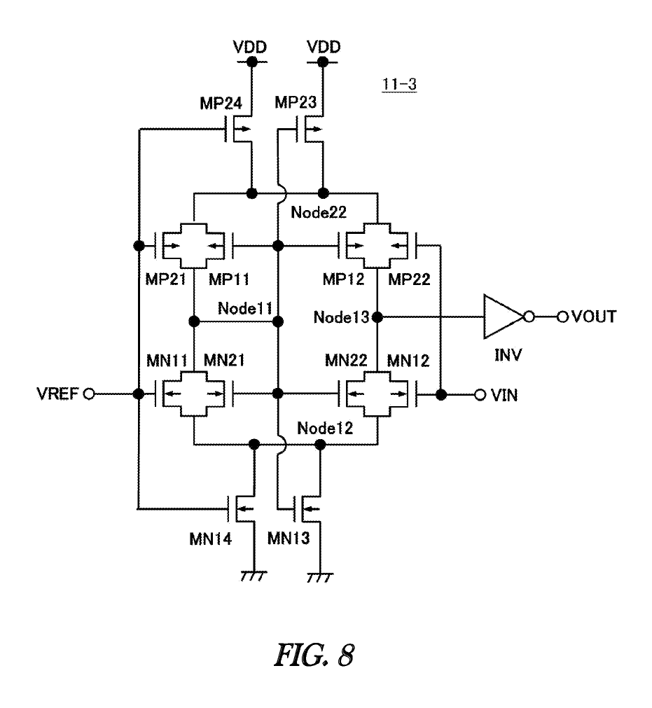

Next, referring to FIG. 8, the description will be made about an input receiver circuit 11-3 according to various embodiments. The input receiver circuit 11-3 is a type referred to as a quad-coupled receiver (QCR) type. The input receiver circuit 11-3 has a configuration like a combination of the input receiver circuit 11-1 of the first embodiment and the input receiver circuit 11-2 of the second embodiment. The input receiver circuit 11-3 of the QCR type has an advantage that it is possible to expand an input signal timing margin in a low voltage operation.

In FIG. 8, components corresponding to the components as shown in FIG. 2 or 7 are denoted by the same reference numerals. In FIG. 8, the gate common connecting point Node 11 also includes the gate common connecting point Node 21, while the drain common connecting point Node 13 also includes the drain common connecting point Node 21.

Here, it is assumed that the names of the first to sixth transistors of some embodiments are employed as the names of the transistors composing the input receiver circuit 11-3. In such a case, the PMOS transistors MP23 and MP24 are referred to as the seventh and eighth transistors, the NMOS transistors MN21 and MN22 are referred to as the ninth and tenth transistors, and the PMOS transistors MP21 and MP22 are referred to as the eleventh and twelfth transistors, respectively. The PMOS transistors MP11 and MP12, which are the third and fourth transistors, configure a first current mirror circuit, while the NMOS transistors MN21 and MN22, which are the ninth and tenth transistors, configure a second current mirror.

Alternatively, it is assumed that the names of the first to sixth transistors of some embodiments are employed as the names of the transistors composing the input receiver circuit 11-3. In such a case, the NMOS transistors MN13 and MN14 are referred to as the seventh and eighth transistors, the PMOS transistors MP11 and MP12 are referred to as the ninth and tenth transistors, and the NMOS transistors MN11 and MN12 are referred to as the eleventh and twelfth transistors, respectively. The NMOS transistors MN21 and MN22, which are the third and fourth transistors, form a first current mirror circuit, while the PMOS transistors MP11 and MP12, which are the ninth and tenth transistors, form a second current mirror.

An operation of the input receiver circuit 11-3 can be easily understood from the descriptions of prior embodiments, and therefore its description is omitted.

In the present embodiment, both of the NMOS transistor MN14 and the PMOS transistor MP24 operate as current adjustment circuits to adjust a current, which passes through the input receiver circuit 11-3 according to the reference voltage VREF. Herewith, the input receiver circuit 11-3 can ensure stable input-output characteristics without the influence of the variation of the reference voltage VREF. In addition, the present embodiment can expand the input signal timing margin as mentioned above.

### CONCLUSION

In some embodiments, a semiconductor device may include: first and second power supply lines; a reference voltage supply line; an input voltage supply line; first, second and third nodes; a first transistor having a gate node coupled to the first node, one of source and drain nodes coupled to the first power supply line, and the other of source and drain nodes coupled to the first node; a second transistor having a gate node coupled to the first node, one of source and drain nodes coupled to the first power supply line, and the other of source and drain nodes coupled to the third node; a third transistor having a gate node coupled to the reference voltage supply line, one of source and drain nodes coupled to the second node, and the other of source and drain nodes coupled to the first node; a fourth transistor having a gate node coupled to the input voltage supply line, one of source and drain nodes coupled to the second node, and the other of source and drain nodes coupled to the third node; a fifth transistor having a gate node coupled to the first node, one of source and drain nodes coupled to the second power supply line, and the other of source and drain nodes coupled to the second node; and a sixth transistor having a gate node coupled to the reference voltage supply line, one of source and drain nodes coupled to the second power supply line, and the other of source and drain nodes coupled to the second node.

Although various embodiments have been described above, the disclosure is not limited to these embodiments. It will be appreciated by those skilled in the art that various changes in form and details may be made therein without departing from the scope of the present disclosure, and as defined by the claims. For example, although each of the embodiments previously described is configured to obtain an inverted output, a configuration may also be employed to provide an output that is not inverted. Such a differential amplifier circuit is used in a semiconductor device disclosed in U.S. Pat. No. 6,339,344, the disclosure of which is incorporated herein by reference in its entirety.

What is claimed is:

1. A semiconductor device comprising:
first and second power supply lines;
a reference voltage supply line;
an input voltage supply line;
first, second and third nodes;
a first transistor having a gate node coupled to the first node, one of source and drain nodes coupled to the first power supply line, and another of source and drain nodes coupled to the first node;
a second transistor having a gate node coupled to the first node, one of source and drain nodes coupled to the first power supply line, and another of source and drain nodes coupled to the third node;
a third transistor having a gate node coupled to the reference voltage supply line, one of source and drain nodes coupled to the second node, and another of source and drain nodes coupled to the first node;
a fourth transistor having a gate node coupled to the input voltage supply line, one of source and drain nodes coupled to the second node, and another of source and drain nodes coupled to the third node;
a fifth transistor having a gate node coupled to the first node, one of source and drain nodes coupled to the second power supply line, and another of source and drain nodes coupled to the second node; and
a sixth transistor having a gate node coupled to the reference voltage supply line, one of source and drain nodes coupled to the second power supply line, and another of source and drain nodes coupled to the second node.

2. The semiconductor device as claimed in claim 1, wherein each of the first and second transistors includes a PMOS transistor, and each of the third, fourth, fifth and sixth transistors includes an NMOS transistor.

3. The semiconductor device as claimed in claim 1, wherein each of the first and second transistors includes an NMOS transistor, and each of the third, fourth, fifth and sixth transistors includes a PMOS transistor.

4. The semiconductor device as claimed in claim 1, wherein the gate node of the sixth transistor is directly connected to the reference voltage supply line.

5. The semiconductor device as claimed in claim 1, further comprising:
a seventh transistor having a gate node coupled to the reference voltage supply line, one of source and drain nodes coupled to the first power supply line, and another of source and drain nodes coupled to the first node;
an eighth transistor having a gate node coupled to the input voltage supply line, one of source and drain nodes coupled to the first power supply line, and another of source and drain nodes coupled to the third node;
a ninth transistor having a gate node coupled to the first node, one of source and drain nodes coupled to the second node, and another of source and drain nodes coupled to the first node;
a tenth transistor having a gate node coupled to the first node, one of source and drain nodes coupled to the second node, and another of source and drain nodes coupled to the third node;
an eleventh transistor having a gate node coupled to the first node, one of source and drain nodes coupled to the first power supply line, and another of source and drain nodes coupled to the one of source and drain nodes of each of the first, second, seventh and eighth transistors; and
a twelfth transistor having a gate node coupled to the reference voltage supply line, one of source and drain nodes coupled to the first power supply line, and another of source and drain nodes coupled to the one of source and drain nodes of each of the first, second, seventh and eighth transistors.

6. The semiconductor device as claimed in claim 5, wherein each of the first, second, seventh, eighth, eleventh and twelfth transistors includes a PMOS transistor, and each of the third, fourth, fifth, sixth, ninth and tenth transistors includes an NMOS transistor.

7. The semiconductor device as claimed in claim 5, wherein each of the first, second, seventh, eighth, eleventh and twelfth transistors includes an NMOS transistor, and each of the third, fourth, fifth, sixth, ninth and tenth transistors includes a PMOS transistor.

8. The semiconductor device as claimed in claim 5, wherein the gate node of each of the sixth and twelfth transistors is directly connected to the reference voltage supply line.
